(19) United States
(12) Patent Application Publication
(10) Pub. No.: US 2026/0344033 A1
(43) Pub. Date: Oct. 29, 2026

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Chia-Hung CHOU, Hsinchu City (TW); Bo-Yu LAI, Taipei City (TW); Wei-Yang LEE, Taipei City (TW); Ka-Hing FUNG, Zhudong Township (TW); Tsung-Lin LEE, Hsinchu City (TW)

(73) Assignee: Taiwan Semiconductor Manufacturing Company, Ltd., Hsinchu (TW)

(21) Appl. No.: 19/192,145

(22) Filed: Apr. 28, 2025

(51) Int. Cl. H10D 84/85; H10D 30/00; H10D 30/01; H10D 30/43; H10D 62/10; H10D 64/01; H10D 64/27; H10D 64/66; H10D 84/01

(52) U.S. Cl. CPC H10D 84/851; H10D 30/014; H10D 30/0191; H10D 30/43; H10D 30/502; H10D 62/116; H10D 62/121; H10D 64/017; H10D 64/021; H10D 64/518; H10D 64/679; H10D 84/0184; H10D 84/0188; H10D 84/856

(57) ABSTRACT

Semiconductor structures and methods for forming the same are provided. The semiconductor structure includes a plurality of nanostructures formed over a substrate, and a gate structure formed on the nanostructures, and the gate structure includes a gate dielectric layer. The semiconductor structure includes a gate spacer layer formed on a sidewall of the gate structure, wherein a dielectric constant of the gate dielectric layer is greater than a dielectric constant of the gate spacer layer. The semiconductor structure includes an S/D structure formed adjacent to the gate structure, and an inner spacer layer between the S/D structure and the gate structure. The inner spacer layer includes a first layer, a second layer and a third layer, and a dielectric constant of the second layer is smaller than a dielectric constant of the first layer and a dielectric constant of the third layer.

### BACKGROUND

The electronics industry is experiencing ever-increasing demand for smaller and faster electronic devices that are able to perform a greater number of increasingly complex and sophisticated functions. Accordingly, there is a continuing trend in the semiconductor industry to manufacture low-cost, high-performance, and low-power integrated circuits (ICs). So far, these goals have been achieved in large part by scaling down semiconductor IC dimensions (e.g., minimum feature size) and thereby improving production efficiency and lowering associated costs. However, such miniaturization has introduced greater complexity into the semiconductor manufacturing process. Thus, the realization of continued advances in semiconductor ICs and devices calls for similar advances in semiconductor manufacturing processes and technology.

Recently, multi-gate devices have been introduced in an effort to improve gate control by increasing gate-channel coupling, reduce OFF-state current, and reduce short-channel effects (SCEs). However, integration of fabrication of the multi-gate devices can be challenging.

### BRIEF DESCRIPTION OF THE DRAWINGS

Aspects of the present disclosure are best understood from the following detailed description when read with the accompanying Figures. It should be noted that, in accordance with the standard practice in the industry, various features are not drawn to scale. In fact, the dimensions of the various features may be arbitrarily increased or reduced for clarity of discussion.

FIGS. 1A to 1E illustrate perspective views of intermediate stages of manufacturing a semiconductor structure in accordance with some embodiments.

FIGS. 2A to 2L illustrate cross-sectional representations of various stages of manufacturing the semiconductor structure shown along line A-A′ in FIG. 1E in accordance with some embodiments.

FIG. 2L′ illustrates a cross-sectional view of a semiconductor structure, in accordance with some embodiments.

FIGS. 3A-3E illustrate enlarged cross-sectional representations of various stages of manufacturing an inner spacer layer shown in region A of FIG. 2G, in accordance with some embodiments.

FIGS. 4A-4D illustrate enlarged cross-sectional representations of various stages of manufacturing a semiconductor structure, in accordance with some embodiments.

FIG. 5 illustrates a cross-sectional representation of a semiconductor structure, in accordance with some embodiments.

FIG. 6 illustrates a cross-sectional representation of a semiconductor structure, in accordance with some embodiments.

FIG. 7 illustrates a cross-sectional representation of a semiconductor structure, in accordance with some embodiments.

FIG. 8 illustrates a cross-sectional representation of a semiconductor structure, in accordance with some embodiments.

FIG. 9 illustrates a cross-sectional representation of a semiconductor structure, in accordance with some embodiments.

FIG. 10 illustrates a cross-sectional representation of a semiconductor structure, in accordance with some embodiments.

FIGS. 11A-11H illustrate cross-sectional representations of a semiconductor structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numerals are used to designate like elements. It should be understood that additional operations can be provided before, during, and after the method, and some of the operations described can be replaced or eliminated for other embodiments of the method.

The gate all around (GAA) transistor structures described below may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, smaller pitches than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

The fins described below may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins.

Embodiments of semiconductor structures and methods for forming the same are provided. The semiconductor structures may include a number of nanostructures are formed over a substrate. A gate structure is formed on the nanostructures, and an S/D structure formed adjacent to the gate structure. An inner spacer layer is between the gate structure and the S/D structure. The inner spacer layer includes a first layer, a second layer and a third layer. The first layer and the second layer are made of different materials. The second layer and the third layer are made of different materials. The dielectric constant of the second layer is smaller than the dielectric constant of the first layer and the dielectric constant of the third layer. The second layer is between the first layer and the second layer. The second layer is used to reduce the dielectric constant of the inner spacer layer. Therefore, the parasitic capacitance is reduced by forming the second layer with a relative low k material. Therefore, the performance of semiconductor device structure is improved. The source/drain structures or S/D region(s) may refer to a source or a drain, individually or collectively dependent upon the context.

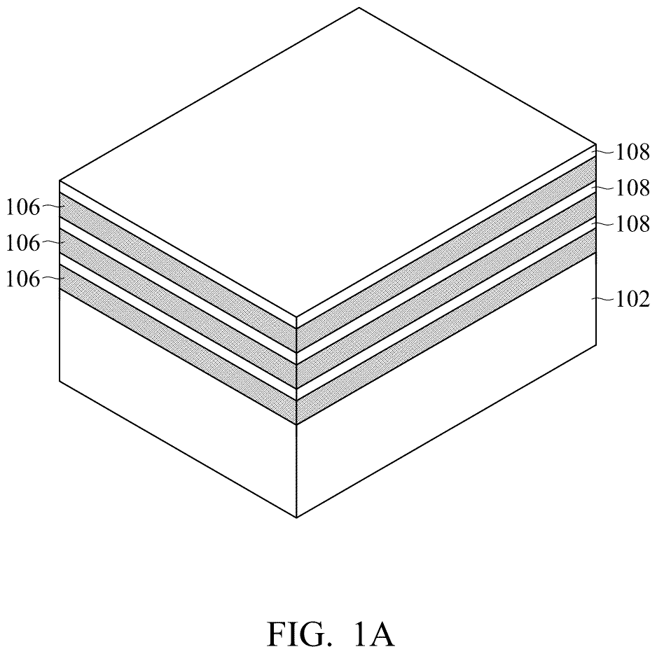

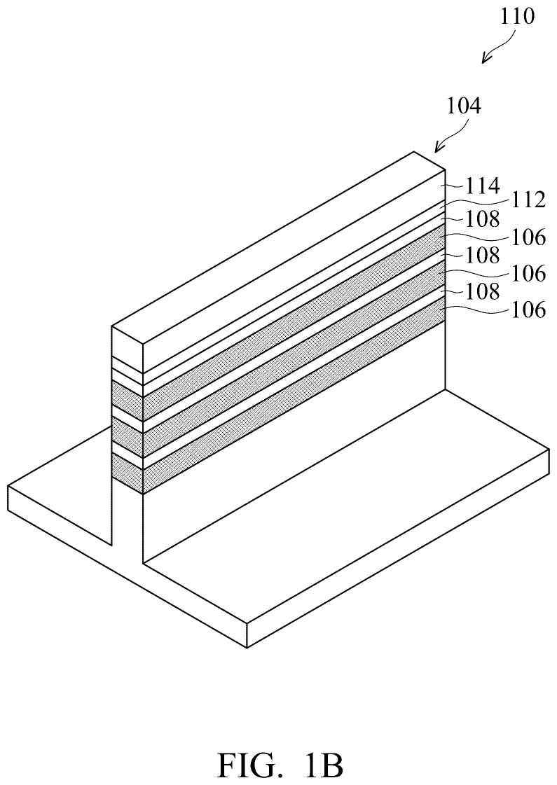

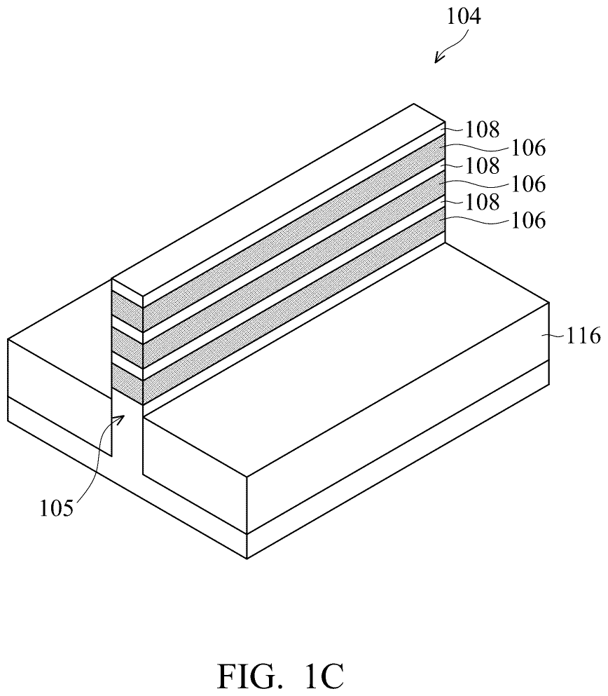

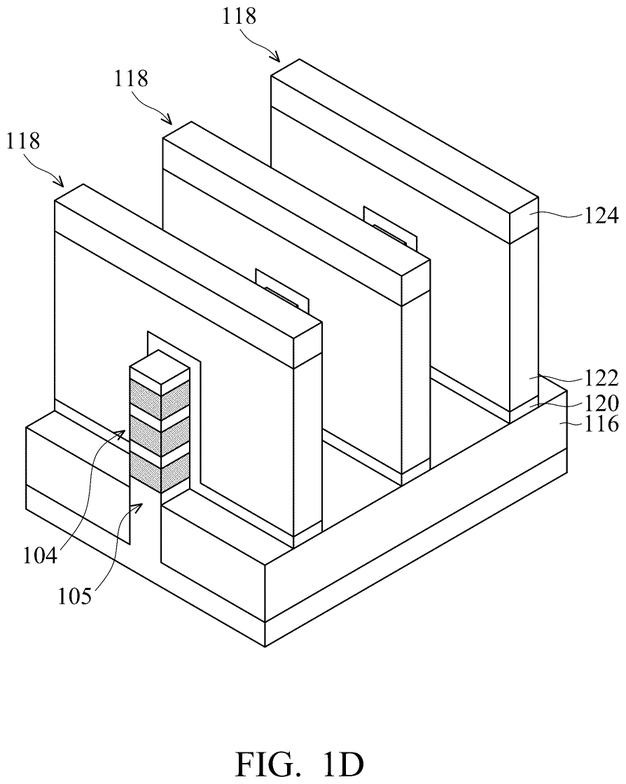

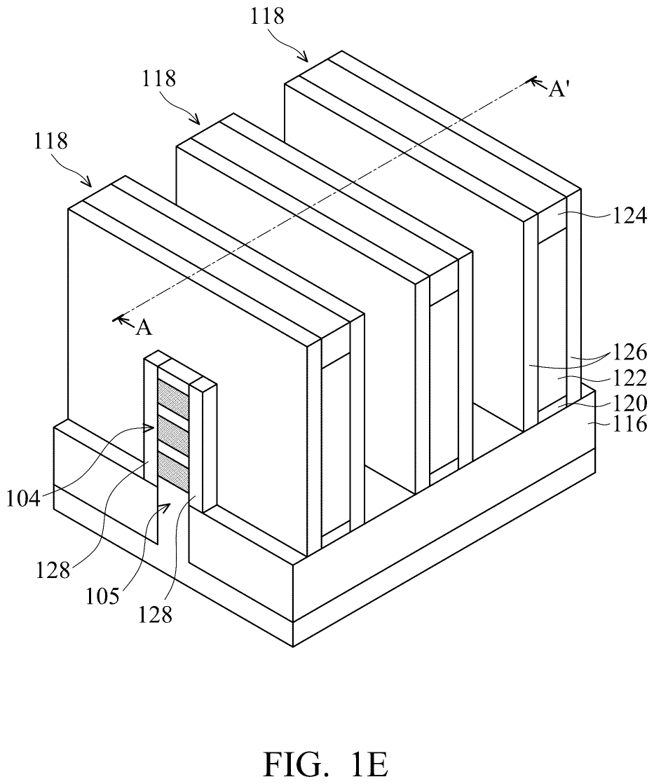

FIGS. 1A to 1E illustrate perspective views of intermediate stages of manufacturing a semiconductor structure 100a, in accordance with some embodiments. As shown in FIG. 1A, first semiconductor material layers 106 and second semiconductor material layers 108 are formed over a substrate 102.

The substrate 102 may be a semiconductor wafer such as a silicon wafer. Alternatively or additionally, the substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

In some embodiments, the first semiconductor material layers 106 and the second semiconductor material layers 108 are alternately stacked over the substrate 102. In some embodiment, the first semiconductor material layers 106 and the second semiconductor material layers 108 are made of different semiconductor materials. In some embodiments, the first semiconductor material layers 106 are made of SiGe, and the second semiconductor material layers 108 are made of silicon. It should be noted that although three first semiconductor material layers 106 and three second semiconductor material layers 108 are formed, the semiconductor structure may include more or fewer first semiconductor material layers 106 and second semiconductor material layers 108. For example, the semiconductor structure may include two to five of the first semiconductor material layers 106 and the second semiconductor material layers.

The first semiconductor material layers 106 and the second semiconductor material layers 108 may be formed by using low-pressure chemical vapor deposition (LPCVD), epitaxial growth process, another suitable method, or a combination thereof. In some embodiments, the epitaxial growth process includes molecular beam epitaxy (MBE), metal organic chemical vapor deposition (MOCVD), or vapor phase epitaxy (VPE).

As shown in FIG. 1B, after the first semiconductor material layers 106 and the second semiconductor material layers 108 are formed as a semiconductor material stack over the substrate 102, the semiconductor material stack is patterned to form a fin structure 104, in accordance with some embodiments. In some embodiments, the fin structure 104 includes a base fin structure 105 and the semiconductor material stack of the first semiconductor material layers 106 and the second semiconductor material layers 108.

In some embodiments, the patterning process includes forming a mask structure 110 over the semiconductor material stack, and etching the semiconductor material stack and the underlying substrate 102 through the mask structure 110. In some embodiments, the mask structure 110 is a multilayer structure including a pad oxide layer 112 and a nitride layer 114 formed over the pad oxide layer 112. The pad oxide layer 112 may be made of silicon oxide, which is formed by thermal oxidation or chemical vapor deposition (CVD), and the nitride layer 114 may be made of silicon nitride, which is formed by chemical vapor deposition (CVD), such as low-temperature chemical vapor deposition (LPCVD) or plasma-enhanced CVD (PECVD).

As shown in FIG. 1C, after the fin structure 104 is formed, an isolation structure 116 is formed around the fin structure 104, and the mask structure 110 is removed, in accordance with some embodiments. The isolation structure 116 is configured to electrically isolate active regions (e.g. the fin structure 104) of the semiconductor structure 100 and is also referred to as shallow trench isolation (STI) feature in accordance with some embodiments.

The isolation structure 116 may be formed by depositing an insulating layer over the substrate 102 and recessing the insulating layer so that the fin structure 104 is protruded from the isolation structure 116. In some embodiments, the isolation structure 116 is made of silicon oxide, silicon nitride, silicon oxynitride (SiON), another suitable insulating material, or a combination thereof. In some embodiments, a dielectric liner (not shown) is formed before the isolation structure 116 is formed, and the dielectric liner is made of silicon nitride and the isolation structure formed over the dielectric liner is made of silicon oxide.

As shown in FIG. 1D, after the isolation structure 116 is formed, dummy gate structures 118 are formed across the fin structure 104 and extend over the isolation structure 116, in accordance with some embodiments. The dummy gate structures 118 may be used to define the source/drain regions and the channel regions of the resulting semiconductor structure 100.

In some embodiments, the dummy gate structures 118 include dummy gate dielectric layers 120 and dummy gate electrode layers 122. In some embodiments, the dummy gate dielectric layers 120 are made of one or more dielectric materials, such as silicon oxide, silicon nitride, silicon oxynitride (SiON), HfO₂, HfZrO, HfSiO, HfTiO, HfAlO, or a combination thereof. In some embodiments, the dummy gate dielectric layers 120 are formed using thermal oxidation, chemical vapor deposition (CVD), atomic vapor deposition (ALD), physical vapor deposition (PVD), another suitable method, or a combination thereof.

In some embodiments, the conductive material includes polycrystalline-silicon (poly-Si), poly-crystalline silicon-germanium (poly-SiGe), metallic nitrides, metallic silicides, metals, or a combination thereof. In some embodiments, the dummy gate electrode layers 122 are formed using chemical vapor deposition (CVD), physical vapor deposition (PVD), or a combination thereof.

In some embodiments, hard mask layers 124 are formed over the dummy gate structures 118. In some embodiments, the hard mask layers 124 include multiple layers, such as an oxide layer and a nitride layer. In some embodiments, the oxide layer is silicon oxide, and the nitride layer is silicon nitride.

The formation of the dummy gate structures 118 may include conformally forming a dielectric material as the dummy gate dielectric layers 120. Afterwards, a conductive material may be formed over the dielectric material as the dummy gate electrode layers 122, and the hard mask layer 124 may be formed over the conductive material. Next, the dielectric material and the conductive material may be patterned through the hard mask layer 124 to form the dummy gate structures 118.

As shown in FIG. 1E, after the dummy gate structures 118 are formed, gate spacers 126 are formed along and covering opposite sidewalls of the dummy gate structure 118 and fin spacers 128 are formed along and covering opposite sidewalls of the source/drain regions of the fin structure 104, in accordance with some embodiments.

The gate spacers 126 may be configured to separate source/drain structures from the dummy gate structure 118 and support the dummy gate structure 118, and the fin spacers 128 may be configured to constrain a lateral growth of subsequently formed source/drain structure and support the fin structure 104.

In some embodiments, the gate spacers 126 and the fin spacers 128 are made of a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), and/or a combination thereof. The formation of the gate spacers 126 and the fin spacers 128 may include conformally depositing a dielectric material covering the dummy gate structure 118, the fin structure 104, and the isolation structure 116 over the substrate 102, and performing an anisotropic etching process, such as dry plasma etching, to remove the dielectric layer covering the top surfaces of the dummy gate structure 118, the fin structure 104, and portions of the isolation structure 116.

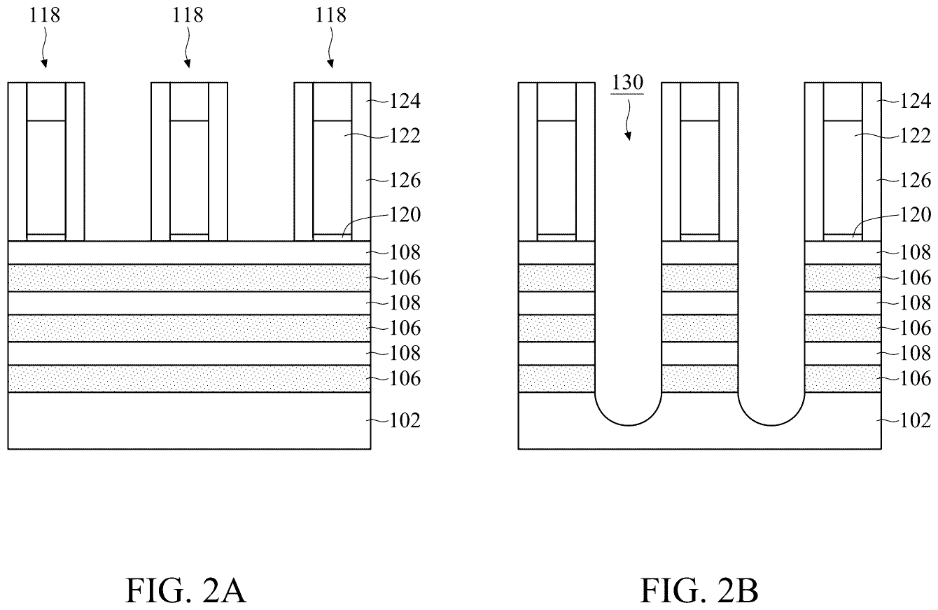

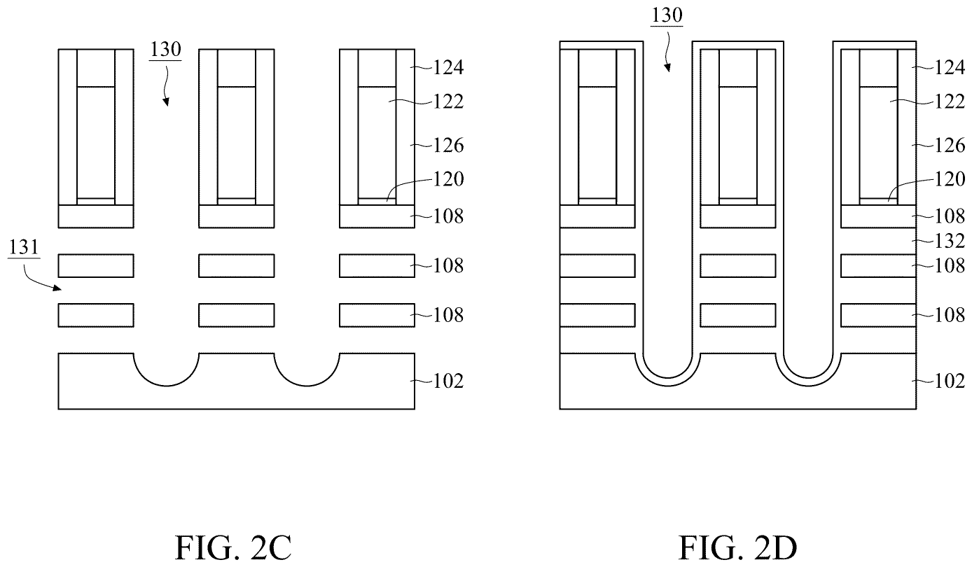

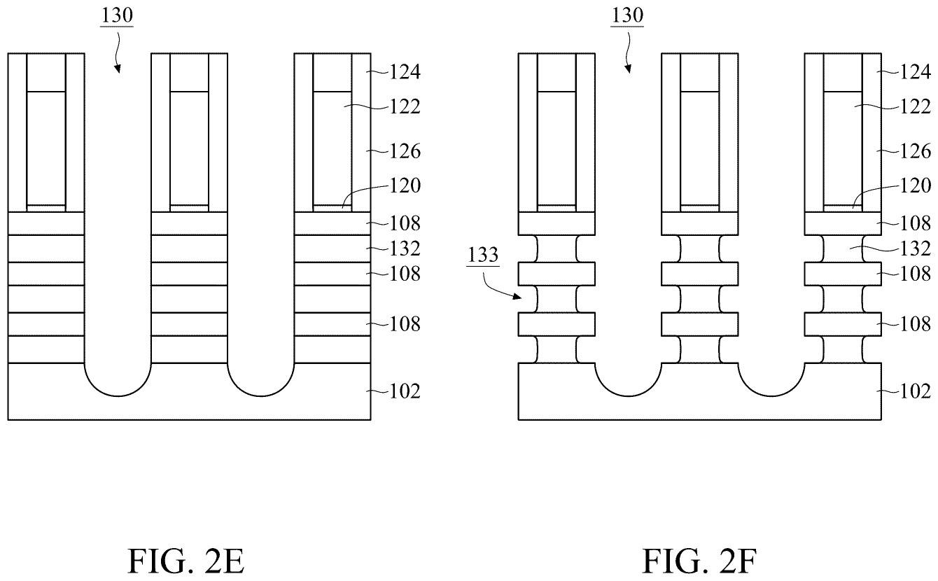

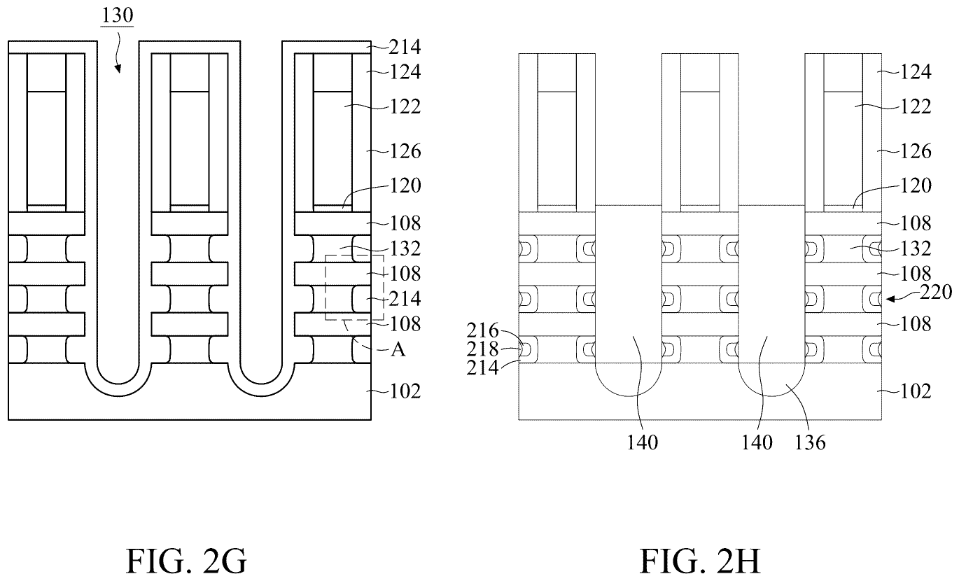

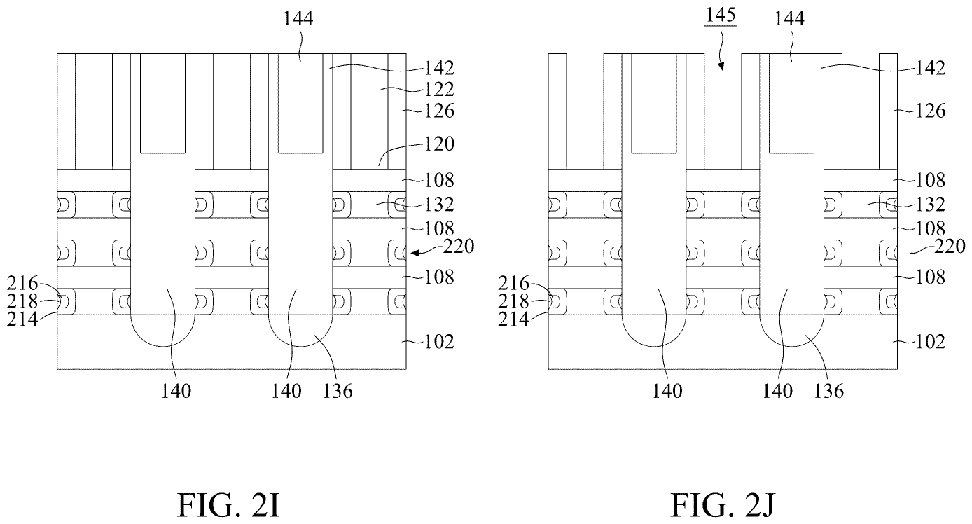

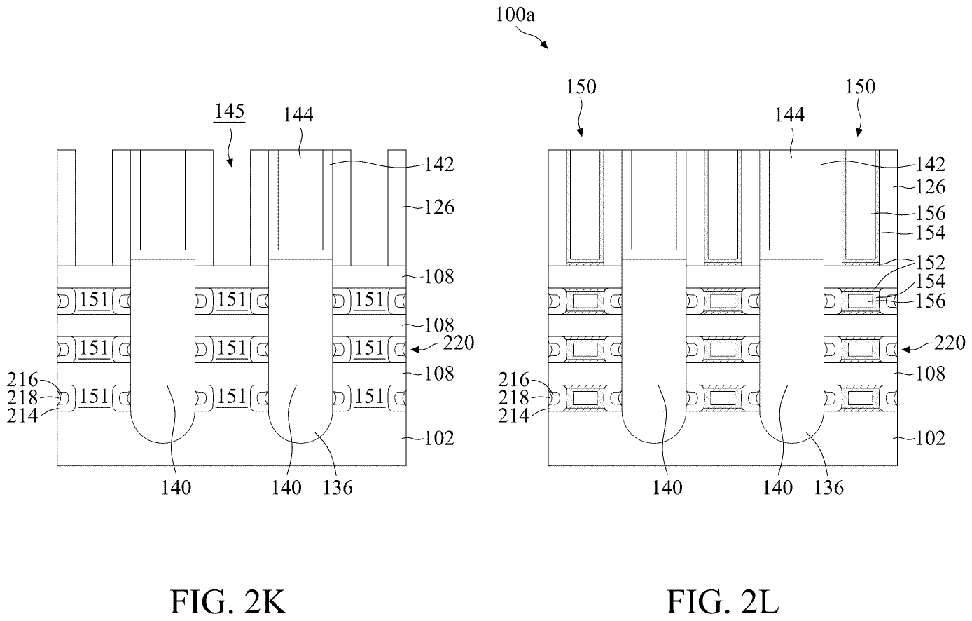

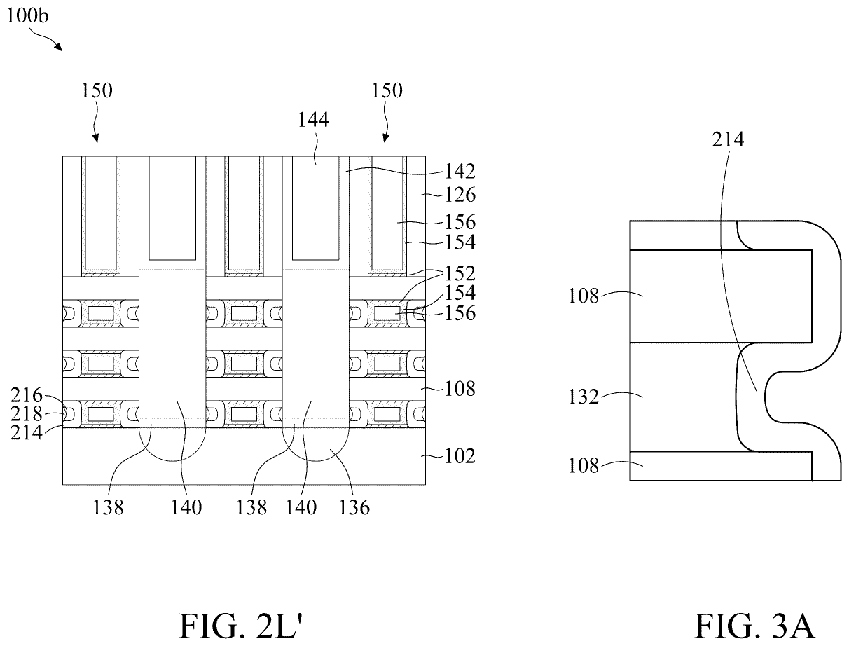

FIGS. 2A to 2L illustrate cross-sectional representations of various stages of manufacturing the semiconductor structure 100a shown along line A-A′ in FIG. 1E in accordance with some embodiments.

More specifically, FIG. 2A illustrates the cross-sectional representation shown along line A-A′ in FIG. 1E, in accordance with some embodiments. As shown in FIG. 2A, the dummy gate structures 118 are formed, and the gate spacers 126 are formed on opposite sidewall surfaces of the dummy gate structures 118.

As shown in FIG. 2B, after the gate spacers 126 and the fin spacers 128 are formed, the source/drain (S/D) regions of the fin structure 104 are recessed to form source/drain (S/D) trenches 130, as shown in in accordance with some embodiments.

More specifically, a portion of the first semiconductor material layers 106 and a portion of the second semiconductor material layers 108 not covered by the dummy gate structures 118 and the gate spacers 126 are removed. The bottom surface of the S/D trench 130 in lower than the top surface of the bottommost first semiconductor material layer 106.

In some embodiments, the fin structure 104 is recessed by performing an etching process. The etching process may be an anisotropic etching process, such as dry plasma etching, and the dummy gate structure 118 and the gate spacers 126 are used as etching masks during the etching process.

Afterwards, as shown in FIG. 2C, after the source/drain (S/D) trenches 130 are formed, a remaining the second semiconductor material layers 106 are removed to form a recess 131, in accordance with some embodiments. The recess 131 is exposed by the S/D trenches 130.

Next, as shown in FIG. 2D, a dummy dielectric layer 132 is formed in the recess 131, in accordance with some embodiments. The dummy dielectric layer 132 is used to replace the second semiconductor material layers 106. As a result, the second semiconductor material layers 108 and the dummy dielectric layer 132 are alternately stacked. The dummy dielectric layer 132 is also called as disposable interposer which will be removed and replaced with a gate structure 150 (shown in FIG. 2J) in the following steps.

The dummy dielectric layer 132 is made of silicon oxide (SiO₂), silicon oxynitride (SiON), aluminum oxide (Al₂O₃) or another applicable materials. In some embodiments, the dummy dielectric layer 132 is formed by an ALD (atomic layer deposition process), flowable CVD or another application process. The advantage of the ALD process is to form uniform and conformal films in the narrow recess 131.

Afterwards, as shown in FIG. 2E, after the dummy dielectric layer 132 is formed, the horizontal portions of the dummy dielectric layer 132 are removed, in accordance with some embodiments. More specifically, the bottom portion and the top portion of the dummy dielectric layer 132 are removed. In some embodiments, the horizontal portions of the dummy dielectric layer 132 are removed by the anisotropic etching process.

Next, as shown in FIG. 2F, a portion of the dummy dielectric layer 132 is removed to form notches 133 between adjacent second semiconductor material layers 108, in accordance with some embodiments. In some embodiments, the etching process is an isotropic etching such as dry chemical etching, remote plasma etching, wet chemical etching, another suitable technique, and/or a combination thereof.

Next, as shown in FIG. 2G, a first layer 214 is formed in the notches 133 and on the sidewall surface of the second semiconductor material layers 108, the sidewall surface of the gate spacers 126, in accordance with some embodiments.

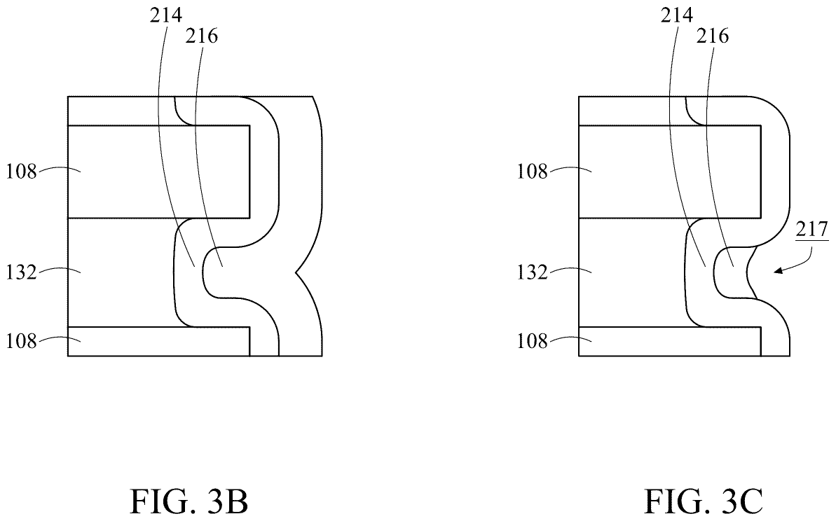

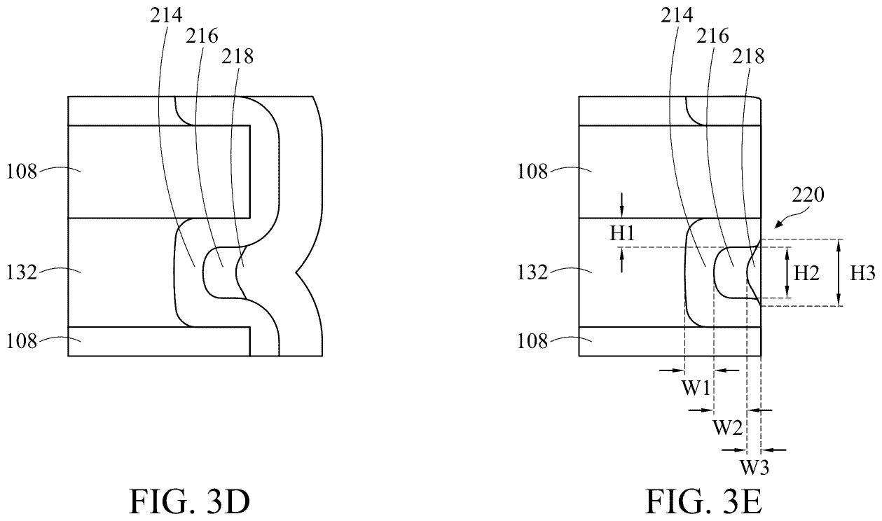

FIGS. 3A-3E illustrate enlarged cross-sectional representations of various stages of manufacturing an inner spacer layer 220 shown in region A of FIG. 2G, in accordance with some embodiments.

As shown in FIG. 3A, the first layer 214 is formed in the notches 133 and on the sidewall surface of the second semiconductor material layers 108, in accordance with some embodiments.

The first layer 214 is conformally formed on the sidewall surfaces of the second semiconductor material layers 108 and the sidewall surfaces of the dummy dielectric layers 132.

The first layer 214 and the dummy dielectric layer 132 are made of different materials. The first layer 214 has a higher etching selectivity with respect to the dummy dielectric layer 132. In other words, the first layer 214 has a higher etching resistance with respect to the dummy dielectric layer 132. Therefore, the first layer 214 is not removed when the dummy dielectric layer 132 is removed at the following process. The dummy dielectric layer 132 will be selectively removed, but the first layer 214 is not damaged or removed.

In some embodiments, the first layer 214 is made of silicon nitride, silicon oxycarbide, silicon carbonitride, silicon oxycarbonitride, or silicon oxynitride. In some embodiments, the first layer 214 is made of SiₐO_{b}C_{c}N_{d}, wherein a:b:c:d=(25~35):(5~15):(30~70):(0~30). The atomic ration of Si of first layer 214 is about 25-35%, the atomic ration of O of first layer 214 is about 5-15 %, the atomic ration of C of first layer 214 is about 30-70 %, and the atomic ration of N of first layer 214 is about 0 -30 %. The dielectric constant of the first layer 214 is about 5.5-6.0.

In some embodiments, the first layer 214 is formed by a deposition process, such as chemical vapor deposition (CVD) process, atomic layer deposition (ALD) process, another applicable process, or a combination thereof.

Afterwards, as shown in FIG. 3B, a second layer 216 is formed on the first layer 214, in accordance with some embodiments. The material of the second layer 216 is different from the material of the first layer 214.

Since the first layer 214 is conformally formed on sidewall surfaces of the second semiconductor material layers 108 and the sidewall surfaces of the dummy dielectric layers 132, the notches 133 is not completely filled with the first layer 132. The notches 133 is filled with the first layer 214 and the second layer 216 after forming the second layer 216. As the deposition process for the second layer 216 continues, the thickness of the second layers 216 continue to grow and eventually close at the middle.

In some embodiments, the second layer 216 is made of oxide, such as silicon oxide (SiOx). The dielectric constant of the second layer 216 is about 3.5-4.0. In some embodiments, the dielectric constant of the second layer 216 is smaller than the dielectric constant of the first layer 214.

Next, as shown in FIG. 3C, a portion of the second layer 216 is removed to expose the first layer 214, in accordance with some embodiments. The portion of the second layer 216 is removed by performing a first removal process. As a result, the second layer 216 has a dishing profile with a recess 217 in the middle. The recess 217 has a curved surface facing the second layer 216. The recess 217 will be filled with a third layer 218 formed later. In some embodiments, the etchant of the first removal process includes diluted HF and NH₄F.

After the first removal process, a cleaning process may be performed on the semiconductor structure 100a to remove some unwanted products. The cleaning process may include a dry clean process, a wet clean process, or a combination thereof. In some embodiments, the wet clean process includes use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. In some embodiments, the dry clean process includes helium (He) and hydrogen (H₂) treatment.

Afterwards, as shown in FIG. 3D, a third layer 218 is formed on the second layer 216 and in the recess 217, in accordance with some embodiments. The recess 217 is completely filled with the third layer 218.

The material of the third layer 218 is different from the material of the second layer 216. In some embodiments, the material of the first layer 214 is the same as the material of the third layer 218. In some other embodiments, the material of the first layer 214 is the different from the material of the third layer 218.

The dielectric constant of the third layer 218 is about 4.5-5.5. The dielectric constant of the second layer 216 is smaller than the dielectric constant of the first layer 214 and the dielectric constant of the third layer 218.

The third layer 218 has a higher etching selectivity with respect to the second layer 216. In other words, the third layer 218 has a higher etching resistance with respect to the second layer 216. Therefore, the third layer 216 is not easily removed at the second removal process (shown in FIG. 3E).

In some embodiments, the third layer 218 is made of silicon nitride, silicon oxycarbide, silicon carbonitride, silicon oxycarbonitride, or silicon oxynitride. In some embodiments, the third layer 218 is made of SiₐO_{b}C_{c}N_{d}, wherein a:b:c:d=(25~35):(5~15):(30~70):(0~30). The atomic ration of Si of first layer 214 is about 25-35%, the atomic ration of O of first layer 214 is about 5 -15 %, the atomic ration of C of first layer 214 is about 30-70 %, and the atomic ration of N of first layer 214 is about 0-30 %. The dielectric constant of the first layer 214 is about 5.5-6.0. In some embodiments, the carbon atomic ration of the first layer 214 is greater than the carbon atomic ration of the third layer 218. When the first layer 214 with relative greater carbon atomic ration, the etching resistance of the first layer 214 is higher than the dummy dielectric layer 132.

Next, as shown in FIG. 3E, a portion of the third layer 218, a portion of the second layer 216 and a portion of the first layer 214 are removed to expose the second semiconductor material layers 108, in accordance with some embodiments. The portion of the third layer 218, the portion of the second layer 216 and the portion of the first layer 214 are removed by performing a second removal process. As a result, an inner spacer layer 220 is formed. The inner spacer layers 220 are configured to separate the source/drain (S/D structures 140 and the gate structures 150 (formed later).

The inner spacer layer 220 includes the first layer 214, the second layer 216 and the third layer 218. The second layer 216 is sandwiched between the first layer 214 and the third layer 218. The second layer 216 is located at the middle portion of the inner spacer layer 220.

A portion of the third layer 218 is surrounded by the second layer 216. A portion of the third layer is embedded in the second layer 216. Another portion of the third layer 218 is extends beyond the sidewall surface of the second layer 216. In other words, the topmost surface of the third layer 218 is higher than the topmost surface of the second layer 216. The topmost surface of the third layer 218 is lower than the topmost surface of the first layer 214.

The outer sidewall surface of the nanostructure 108′ extends beyond the outer sidewall surface of the second layer 216. The outer sidewall surface of the gate spacer 126 extends beyond the outer sidewall surface of the second layer 216. In other words, outer sidewall surface of the nanostructure 108′ extends beyond the interface between the second layer 216 and the third layer 218. The outer sidewall surface of the gate spacer 126 extends beyond the interface between the second layer 216 and the third layer 218.

In some embodiments, the etching gas of the second removal process includes CF₄, CH₄, CHF₃, NF₃ or combination thererof. In some embodiments, the gas of the second removal process includes O₂, N₂ or Ar or combination thererof.

After the second removal process, the sidewall surface of the second semiconductor material layers 108. The sidewall surface of the second semiconductor material layers 108 is substantially aligned with the sidewall surface of the third layer 218, the sidewall surface of the first layer 214.

After the second removal process, a cleaning process may be performed on the semiconductor structure 100a to remove some unwanted products. The cleaning process may include a dry clean process, a wet clean process, or a combination thereof. In some embodiments, the wet clean process includes use of a mixture of deionized (DI) water, ammonium hydroxide, and hydrogen peroxide, a mixture of DI water, hydrochloric acid, and hydrogen peroxide), SPM (a sulfuric peroxide mixture), and or hydrofluoric acid for oxide removal. In some embodiments, the dry clean process includes helium (He) and hydrogen (H₂) treatment.

The fin structure 104 is formed along the first direction (e.g. x-axis). The second semiconductor material layers 108 are formed along the first direction (e.g. x-axis). The first layer 214 has a first width W1 along the first direction (e.g. x-axis). The second layer 216 has a second width W2 along the first direction (e.g. x-axis). The third layer 218 has a third width W3 along the first direction (e.g. x-axis). In some embodiments, the second width W2 of the second layer 216 is greater than the first width W1 of the first layer 214 and the third width W3 of the third layer 218. In some embodiments, the ratio of the first width W1, the second width W2 and the third width W3 is about 1-1.5:3-5:0.5-1.5. In some embodiments, the first width W1 of the first layer 214 is about 1 nm to about 1.5 nm. In some embodiments, the second width W2 of the second layer 216 is about 3 nm to 5 nm. In some embodiments, the third width W3 of the third layer 218 is about 0.5 nm to about 1.5 nm.

The first layer 214 has a first height H1 above the second layer 216 along the vertical direction. The second layer 216 has a second height H2 along the vertical direction. The third layer 218 has a third height H3 along the vertical direction. In some embodiments, the first height H1 of the first layer 214 is about from 1.0 nm to 1.5 nm. In some embodiments, the second height H2 of the second layer 216 is about from 3 nm to 4 nm. In some embodiments, the third height H3 of the third layer 218 is greater than the second height H2 of the second layer 216.

Next, as shown in FIG. 2H, after the inner spacer layer 220 with the first layer 214, the second layer 216 and the third layer 218 is formed, a seed layer 136 is formed in the S/D trench 130, in accordance with some embodiments. Next, the S/D structures 140 are formed in the S/D trench 130 and on the seed layer 136.

The seed layer 136 is used as a seed layer to help the formation of the source/drain (S/D) structures 140 (formed later). Since the lattice of the seed layer 136 is similar to the lattice of the S/D structure 140, the quality of the S/D structure 140 is improved.

In some embodiments, the seed layer 136 is made of undoped Si or undoped SiGe or another applicable material. In some embodiments, the seed layer 136 is formed by epitaxial growth process.

In some embodiments, the S/D structures 140 are in-situ doped during the epitaxial growth process. For example, the S/D structures 140 may be the epitaxially grown SiGe doped with boron (B). For example, thee S/D structures 140 may be the epitaxially grown Si doped with carbon to form silicon:carbon (Si:C) source/drain features, phosphorous to form silicon: phosphor (Si:P) source/drain features, or both carbon and phosphorous to form silicon carbon phosphor (SiCP) source/drain features. In some embodiments, the S/D structures 140 are doped in one or more implantation processes after the epitaxial growth process.

The top surface of the S/D structure 140 is higher than the topmost surface of the inner spacer layer 220. In addition, the top surface of the S/D structure 140 is higher than the bottom surface of the gate spacer layer 126. The top surface of the S/D structure 140 is higher than the topmost second semiconductor material layer 108.

Afterwards, as shown in FIG. 2I, after the S/D structures 140 are formed, a contact etch stop layer (CESL) 142 is conformally formed to cover the S/D structures 140 and an interlayer dielectric (ILD) layer 144 is formed over the contact etch stop layers 142, in accordance with some embodiments.

In some embodiments, the contact etch stop layer 142 is made of a dielectric materials, such as silicon nitride, silicon oxide, silicon oxynitride, another suitable dielectric material, or a combination thereof. The dielectric material for the contact etch stop layers 142 may be conformally deposited over the semiconductor structure by performing chemical vapor deposition (CVD), ALD, other application methods, or a combination thereof.

The ILD layer 144 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The ILD layer 144 may be formed by chemical vapor deposition (CVD), physical vapor deposition, (PVD), atomic layer deposition (ALD), or other applicable processes.

After the contact etch stop layer 142 and the ILD layer 144 are deposited, a planarization process such as CMP or an etch-back process may be performed until the gate electrode layers 120 of the dummy gate structures 118 are exposed, as shown in FIG. 2I, in accordance with some embodiments.

Afterwards, as shown in FIG. 2J, the dummy gate structures 118 are removed, in accordance with some embodiments. More specifically, the dummy gate electrode layer 122 and the dummy gate dielectric layer 120 are removed to form trenches 145.

For example, when the dummy gate electrode layers 122 are polysilicon, a wet etchant such as a tetramethylammonium hydroxide (TMAH) solution may be used to selectively remove the dummy gate electrode layers 122. Afterwards, the dummy gate dielectric layers 120 may be removed using a plasma dry etching, a dry chemical etching, and/or a wet etching.

Afterwards, as shown in FIG. 2K, the dummy dielectric layers 132 are removed t form nanostructures 108′ (or channel layers 108′) with the second semiconductor material layers 108, in accordance with some embodiments. As a result, a number of gaps 151 are formed between the nanostructures 108′ (or channel layers 108′). The S/D structures 140 are attached to the nanostructures 108′. The fin structure 104 includes the nanostructures 108′.

In some embodiment, where the nanostructures 108′ (or channel layers 108′) consist essentially of silicon (Si) and the dummy dielectric layers 132 are formed of silicon oxide, the dummy layer 132 is selectively removed by using a selective wet etch process or a selective dry etch process. In some embodiment, the selective dry etching process includes use of carbon tetrafluoride (CF₄), nitrogen trifluoride (NF₃), hydrogen (H₂), or a mixture thereof. In some embodiment, the selective wet etching process includes use of hydrofluoric acid, ammonium fluoride, or a mixture thereof.

Since the dummy dielectric layer 132 and the first layer 214 of the inner spacer layer 220 are made of different materials and the dummy dielectric layer 132 and the first layer 214 of the inner spacer layer 220 have different etching selectivity, the dummy dielectric layer 132 is removed but the first layer 214 of the inner space layer 220 is not removed.

It should be noted that, the gaps 151 are formed by removing the dummy dielectric layer 132, rather than the second semiconductor material layers 106. Therefore, the unwanted by-products, such as Ge-containing residues, which are formed due to removal of the second semiconductor material layers 106, are not remaining in the gaps 151. The clean surfaces of the gaps 151 are provided, and the clean surfaces are helpful for deposition of a gate structure 150 (shown in FIG. 2L).

During the formation of the semiconductor devices, Ge in the semiconductor material layers may diffuse into the channel layers during the manufacturing processes, such as thermal processes. The performance of the resulting devices may therefore be undermined due to the Ge diffusion. Accordingly, in some embodiments of the present disclosure, the semiconductor material layers 106 are replaced with dielectric dummy layer 132 in a relatively early stage of the manufacturing process (e.g. before the high-temperature thermal processes are performed). Therefore, the issues of Ge diffusion may be reduced or avoided.

Furthermore, the second semiconductor material layers 106 is replaced with the dummy dielectric layer 132 before formation of the inner spacer layer 220, the unwanted SiGe/Si intermix products at corner of the inner spacer layer 220 can be reduced. Therefore, the performance of the semiconductor structure 100a is improved.

Next, as shown in FIG. 2L, after the nanostructures 108′ are formed, the gate structures 150 are formed to surround the nanostructures 108′ and over the isolation structure 116, in accordance with some embodiments.

After the nanostructures 108′ are formed, the gate structures 150 are formed wrapped around the nanostructures 108′. The gate structure 150 wrap around the nanostructures 108′ to form gate-all-around transistor structures, in accordance with some embodiments. In some embodiments, each of the gate structure 150 includes an interfacial layer 152, a gate dielectric layer 154, and a gate electrode layer 156.

In some embodiments, the interfacial layer 152 are oxide layers formed around the nanostructures 108′ and on the top of the base fin structure 105. In some embodiments, the interfacial layer are formed by performing a thermal process.

In some embodiments, the gate dielectric layers 154 are formed over the interfacial layers, so that the nanostructures 108′ are surrounded (e.g. wrapped) by the gate dielectric layers 154. In addition, the gate dielectric layers 154 also cover the sidewalls of the gate spacers 126 and the inner spacer layers 220, in accordance with some embodiments.

In some embodiments, the dielectric constant of the gate dielectric layers 154 is greater than the dielectric constant of the gate spacer layer 126. In some embodiments, the gate dielectric layers 154 are made of one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the gate dielectric layers 154 are formed using chemical vapor deposition (CVD), atomic layer deposition (ALD), another applicable method, or a combination thereof.

In some embodiments, the gate electrode layer 156 is made of one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layer 156 is formed using chemical vapor deposition (CVD), atomic layer deposition (ALD), electroplating, another applicable method, or a combination thereof.

Other conductive layers, such as work function metal layers, may also be formed in the first gate structure 150, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

After the interfacial layer 152, the gate dielectric layers 154, and the gate electrode layer 156 are formed, a planarization process such as CMP or an etch-back process may be performed until the ILD layer 144 is exposed.

The S/D structure 140 is adjacent to a sidewall of the nanostructures 108. The top surface of the S/D structure 140 is higher than the topmost nanostructure 108. The inner spacer layer 220 is between the S/D structure 140 and the gate structure 150. The sidewall surface of the S/D structure 140 is in contact with the third layer 218 and the first layer 214 of the inner spacer layer 220. Note that the sidewall surface of the S/D structure 140 is not in contact with the second layer 216 of the inner spacer layer 220. The second layer 216 of the inner spacer layer is separated from the S/D structure 140 by the first layer 214.

As shown in FIG. 2L, the inner spacer layer 220 is between the gate structure 150 and the S/D structure 140. The inner spacer layer 220 includes the first layer 214, the second layer 216 and the third layer 218. There is a first interface between the first layer 214 and the second layer 216, and a second interface between the second layer 216 and the third layer 216. Since the dielectric constant of the second layer 216 is lower than that of the first layer 214 and that of the third layer 218, and the second layer 216, the overall dielectric constant of the inner spacer layer 220 can be reduced by forming tri-layers structure, and therefore the parasitic capacitance of the semiconductor structure 100a can be reduced.

FIG. 2L′ illustrates a cross-sectional view of a semiconductor structure 100b, in accordance with some embodiments. The semiconductor structure 100b of FIG. 2L′ includes elements that are similar to, or the same as, elements of the semiconductor structure 100a of FIG. 2L, the difference between FIG. 2L′ and FIG. 2L is that a bottom isolation layer 138 is formed on the seed layer 136, in accordance with some embodiments. The bottom isolation layer 138 is used to reduce the leakage. The S/D structure 140 is formed on the bottom isolation layer 138. The bottom isolation layer 138 is between the seed layer 136 and the S/D structure 140.

The bottom isolation layer 138 is in direct contact with the inner spacer layer 220. More specifically, the bottom isolation layer 138 is in direct contact with the third layer 218 of the inner spacer layer 220. In other words, the third layer 218 of the inner spacer layer 220 is between the bottom isolation layer 138 and the second layer 216 of the inner spacer layer 220.

In some embodiments, the top surface of the bottom isolation layer 138 is lower than the top surface of the bottommost inner spacer layer 220. In some embodiments, the top surface of the bottom isolation layer 138 is substantially coplanar with the top surface of the bottommost inner spacer layer 220. In some embodiments, the bottom isolation layer 138 is made of SiN, SiON, SiOCN, SiOC, SiCN, SiOx, AlOx, HfOx or another applicable material. In some embodiments, the bottom isolation layer 138 is formed by a deposition process, such as CVD process, ALD process, another applicable process, or a combination thereof. In some embodiments, the bottom isolation layer 138 is formed by an ALD or an ALD-like process.

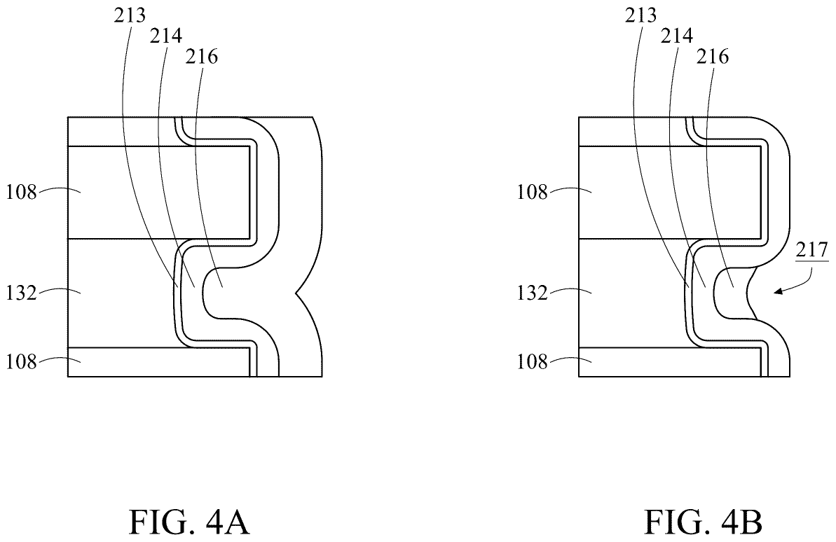

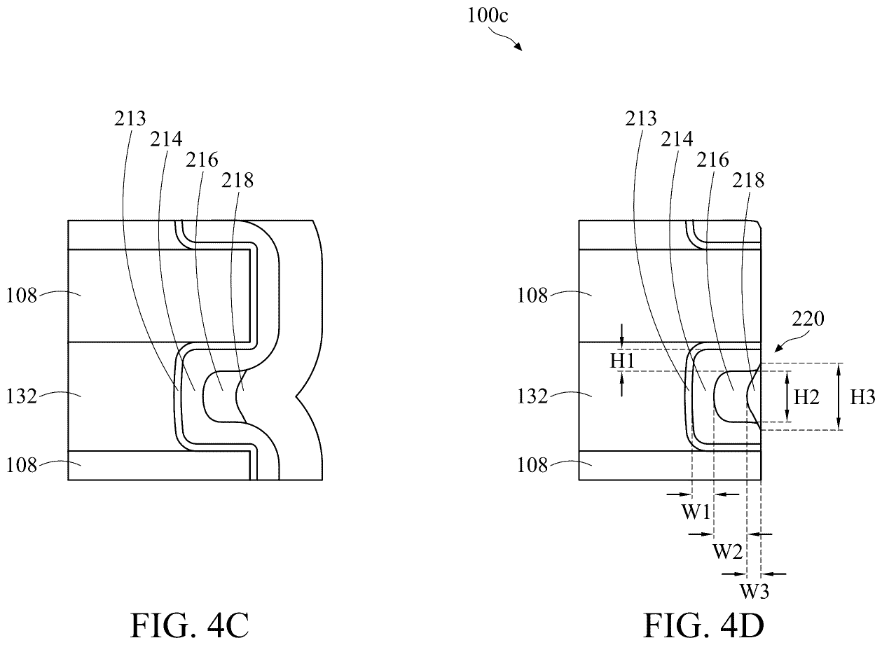

FIGS. 4A-4D illustrate enlarged cross-sectional representations of various stages of manufacturing a semiconductor structure 100c, in accordance with some embodiments.

The semiconductor structure 100b of FIGS. 4A-4D includes elements that are similar to, or the same as, elements of the semiconductor structure 100a of FIG. 3A-3E, the difference between FIGS. 4A-4D and FIGS. 3A-3E is that an additional thin layer 213 is formed before forming the first layer 214.

As shown in FIG. 4A, a thin layer 213 is formed in the notches 133 and on the sidewall surface of the second semiconductor material layers 108, the sidewall surface of the gate spacers 126, in accordance with some embodiments. Next, the first layer 214 is formed on the thin layer 213.

The thin layer 213 is conformally formed on the sidewall surfaces of the second semiconductor material layers 108 and the sidewall surfaces of the dummy dielectric layers 132. The thin layer 213 and the first layer 214 are made of different materials.

The thin layer 213 has a higher etching selectivity with respect to the dummy dielectric layer 132. In other words, the thin layer 213 has a higher etching resistance with respect to the dummy dielectric layer 132. Therefore, the thin layer 213 is not removed when the dummy dielectric layer 132 is removed at the following process. The dummy dielectric layer 132 will be selectively removed, but the thin layer 213 is not damaged or removed.

In some embodiments, the thin layer 213 is made of silicon nitride, silicon oxycarbide, silicon carbonitride, silicon oxycarbonitride, or silicon oxynitride. In some embodiments, the thin layer 213 is made of SiON. In some embodiments, the thin layer is formed by forming a silicon oxide layer and then performing a treatment process, and the treatment process includes using NH₃. In some embodiments, the thin layer 213 has a thickness about 2 angstrom to 6 angstrom.

Next, as shown in FIG. 4B, a portion of the second layer 216 is removed to expose the first layer 214, in accordance with some embodiments. The portion of the second layer 216 is removed by performing a first removal process. As a result, the second layer 216 has a dishing profile with a recess 217 in the middle. In some embodiments, the etchant of the first removal process includes diluted HF and NH₄F.

Afterwards, as shown in FIG. 4C, a third layer 218 is formed on the second layer 216 and in the recess 217, in accordance with some embodiments. The recess 217 is completely filled with the third layer 218.

The material of the third layer 218 is different from the material of the second layer 216. In some embodiments, the material of the first layer 214 is the same as the material of the third layer 218. In some other embodiments, the material of the first layer 214 is the different from the material of the third layer 218.

Next, as shown in FIG. 4D, a portion of the third layer 218, a portion of the second layer 216 and a portion of the first layer 214 are removed to expose the second semiconductor material layers 108, in accordance with some embodiments. The portion of the third layer 218, the portion of the second layer 216 and the portion of the first layer 214 are removed by performing a second removal process. As a result, the inner spacer layer 220 is formed.

The inner spacer layer 220 includes the thin layer 213, the first layer 214, the second layer 216 and the third layer 218. There is a first interface between the thin layer 213 and the first layer 214, a second interface between the first layer 214 and the second layer 216, and a third interface between the second layer 216 and the third layer 218. The second layer 216 is separated from the S/D structure 140 by the thin layer 213 and the first layer 214.

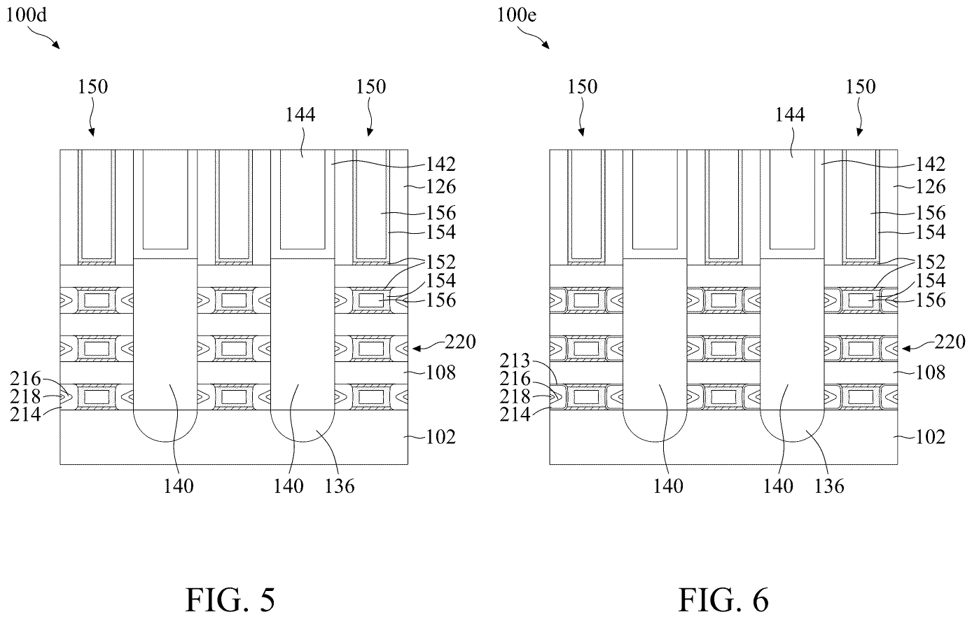

FIG. 5 illustrates a cross-sectional representation of a semiconductor structure 100d, in accordance with some embodiments. The semiconductor structure 100d of FIG. 5 includes elements that are similar to, or the same as, elements of the semiconductor structure 100a of FIG. 2L, the difference between FIG. 5 and FIG. 2L is that the interface between the first layer 214 and the second layer 216 has a V-shaped structure, and the interface between the second layer 216 and the third layer 218 also has a V-shaped structure.

FIG. 6 illustrates a cross-sectional representation of a semiconductor structure 100e, in accordance with some embodiments. The semiconductor structure 100e of FIG. 6 includes elements that are similar to, or the same as, elements of the semiconductor structure 100d of FIG. 5, the difference between FIG. 6 and FIG. 5 is that the inner spacer layer 220 includes four layers. The thin layer 213 is formed before the first layer 214.

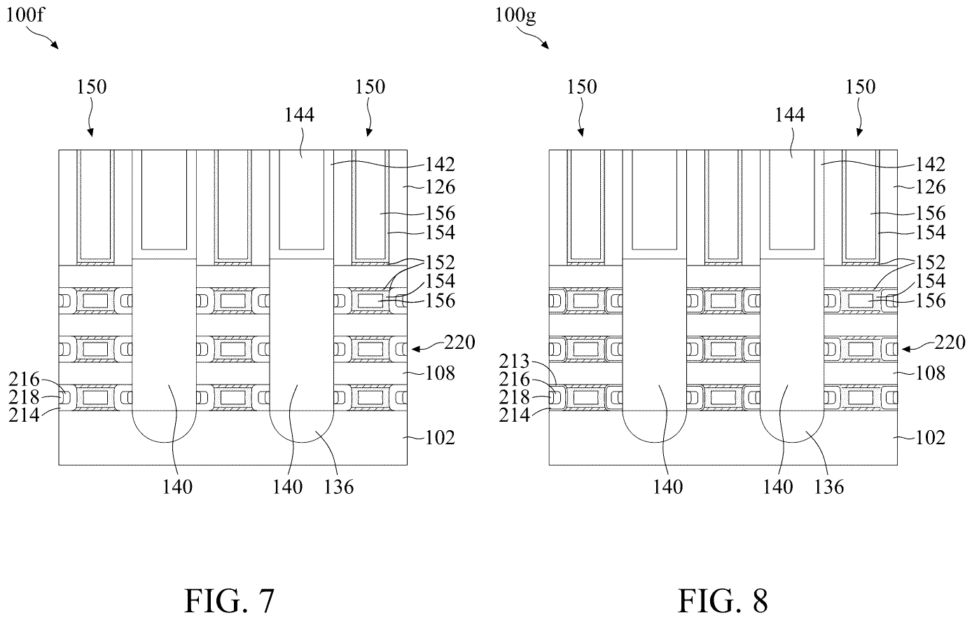

FIG. 7 illustrates a cross-sectional representation of a semiconductor structure 100f, in accordance with some embodiments. The semiconductor structure 100f of FIG. 7 includes elements that are similar to, or the same as, elements of the semiconductor structure 100a of FIG. 2L, the difference between FIG. 7 and FIG. 2L is that the interface between the first layer 214 and the second layer 216 has a rectangular-shaped structure, and the interface between the second layer 216 and the third layer 218 also has a rectangular-shaped structure.

FIG. 8 illustrates a cross-sectional representation of a semiconductor structure 100g, in accordance with some embodiments. The semiconductor structure 100g of FIG. 8 includes elements that are similar to, or the same as, elements of the semiconductor structure 100f of FIG. 7, the difference between FIG. 6 and FIG. 5 is that the inner spacer layer 220 includes four layers. The thin layer 213 is formed before the first layer 214.

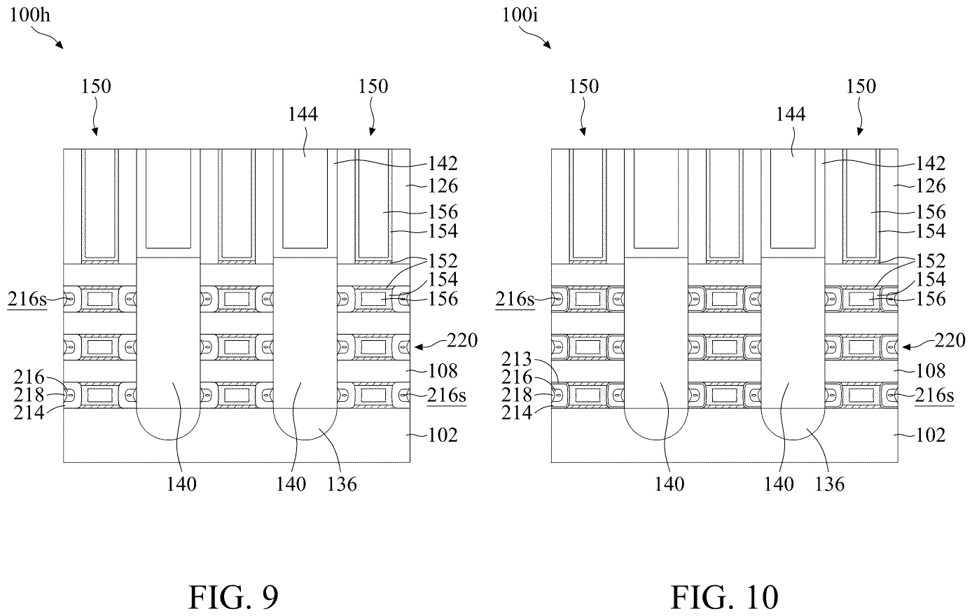

FIG. 9 illustrates a cross-sectional representation of a semiconductor structure 100h, in accordance with some embodiments. The semiconductor structure 100h of FIG. 9 includes elements that are similar to, or the same as, elements of the semiconductor structure 100a of FIG. 2L, the difference between FIG. 7 and FIG. 2L is that the second layer 216 has a seam 216s. The seam 216s is formed in middle portion of the second layer 216. The seam 216s is formed in the middle since the second layer 216 is conformally formed. The seam 216s is an air gap and the overall dielectric constant of the inner spacer layer 220 can be further reduced by forming the seam 216s.

FIG. 10 illustrates a cross-sectional representation of a semiconductor structure 100i, in accordance with some embodiments. The semiconductor structure 100i of FIG. 10 includes elements that are similar to, or the same as, elements of the semiconductor structure 100h of FIG. 9, the difference between FIG. 6 and FIG. 5 is that the inner spacer layer 220 includes four layers. The thin layer 213 is formed before the first layer 214.

It should be noted that the inner spacer layer 220 with the second layer with relative low dielectric constant, and the overall capacitance of the inner spacer layer 220 is reduced by forming the second layer 220.

It should be appreciated that the semiconductor structures 100a to 100i having inner spacer layer 220 with the first layer 214, the second layer 216 and the third layer 218. Since the dielectric constant of the second layer 216 is smaller than the dielectric constant of the first layer 214 and the dielectric constant of the third layer 218. The second layer 216 is between the first layer 214 and the third layer 218. The second layer 216 is used to reduce the dielectric constant of the inner spacer layer 220. Therefore, the parasitic capacitance of the semiconductor structure 100a-100i is reduced by forming the second layer 216 with a relative low k material.

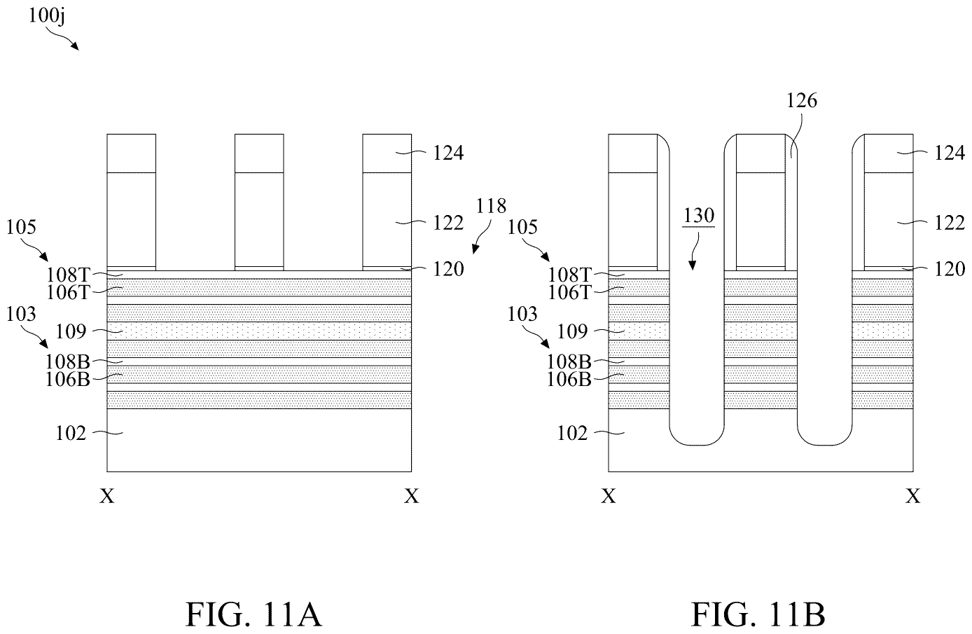

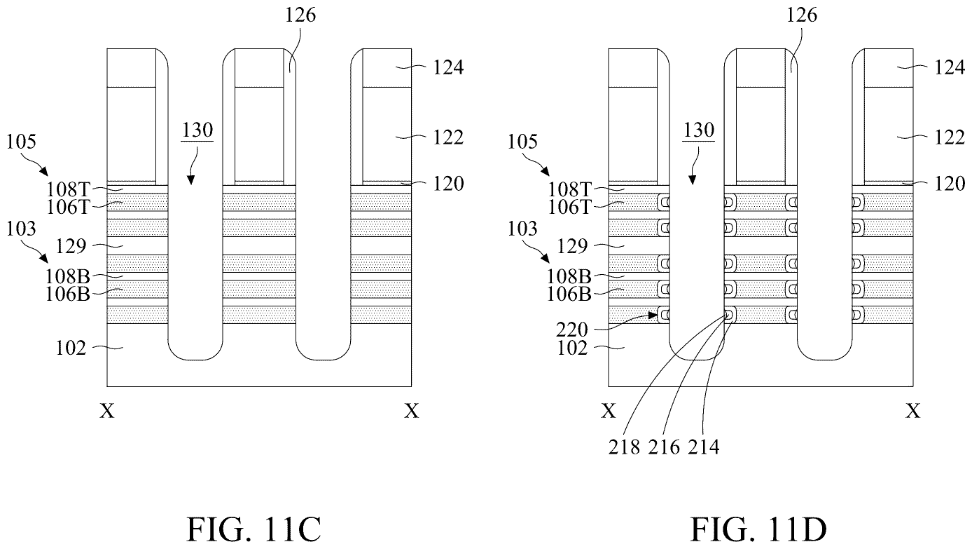

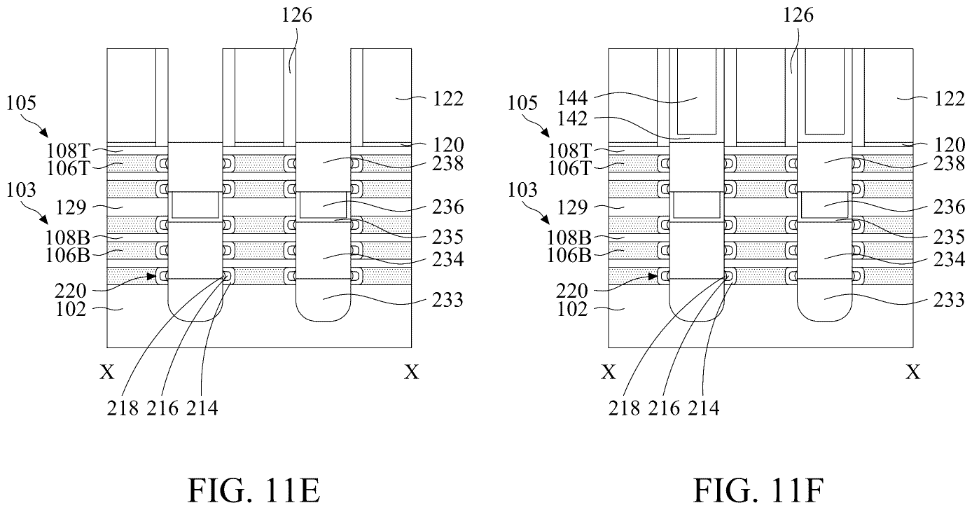

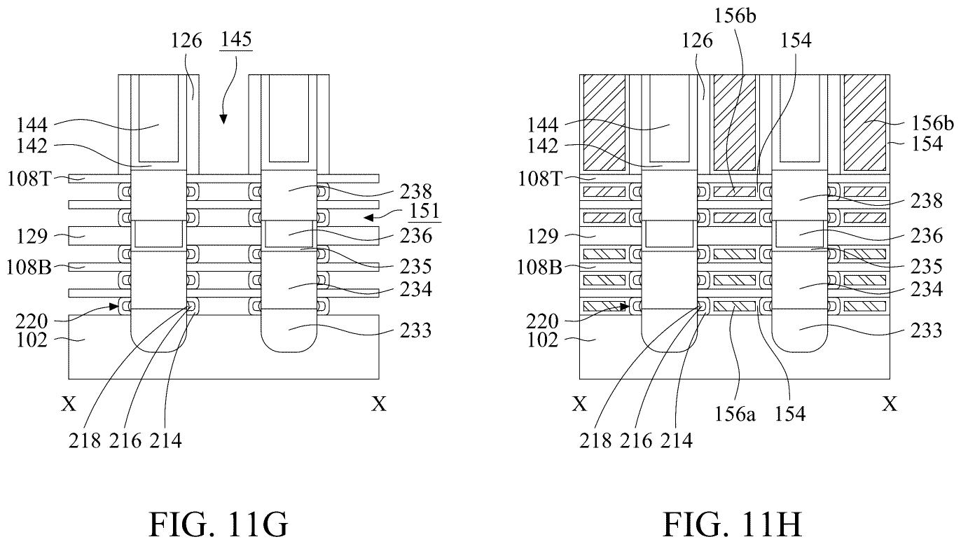

FIGS. 11A-11H illustrate cross-sectional representations of a semiconductor structure 100j, in accordance with some embodiments. The semiconductor structure 100j is a complementary field-effect transistor (CFET). The semiconductor structure 100j of FIG. 11A-11H includes elements that are similar to, or the same as, elements of the semiconductor structure 100a of FIG. 2A-2L.

As shown in FIG. 11A, a first stack structure 103 is formed over a substrate 102, a sacrificial layer 109 is formed over the first stack structure 103 and a second stack structure 105 is formed over the sacrificial layer 109, in accordance with some embodiments. The semiconductor structure 100a is used to form CFET devices in which n-type devices and p-type devices are stacked.

The first stack structure 103 includes the first semiconductor layers 106B and the second semiconductor layers 108B are alternatively stacked. The second stack structure 105 includes the first semiconductor layers 106T and the second semiconductor layers 108T are alternatively stacked. The sacrificial layer 109 is made of first semiconductor layers. In some embodiments, the sacrificial layer 109 is made of SiGe.

The first semiconductor layers 106B and 106T and will be removed to form gaps to accommodate gate materials, in accordance with some embodiments. The second semiconductor layers 108B and 108T will form nanostructures (e.g., nanowires or nanosheets) that laterally extend between source/drain features and serve as the channel for the resulting semiconductor device (such as a nanostructure transistor), in accordance with some embodiments. As the term is used herein, “nanostructures” refers to semiconductor layers that have cylindrical shape, bar shape and/or sheet shape.

The dummy gate structures 118 are formed across the patterned first stack structure 103, the sacrificial layer 109 and the patterned second stack structure 105. In some embodiments, the dummy gate structures 118 extend in the second direction (e.g. Y-axis). That is, the dummy gate structures 118 have longitudinal axes parallel to the second direction (e.g. Y-axis), in accordance with some embodiments. The dummy gate structures 118 are configured as sacrificial structures and will be replaced with the final gate stacks, in accordance with some embodiments

The dummy gate structures 118 may be used to define the source/drain (S/D) regions and the channel regions of the resulting semiconductor structure 100j. In some embodiments, the dummy gate structure 118 include dummy gate dielectric layers 120 and dummy gate electrode layers 122.

Next, as shown in FIG. 11B, after the dummy gate structures 118 are formed, gate spacer layers 126 are formed along and covering opposite sidewalls of the dummy gate structure 118 are formed along and covering opposite sidewalls of the source/drain regions of the fin structure 103, in accordance with some embodiments.

The source/drain (S/D) regions of the first stack structure 103 and the second stack structure 105 are recessed to form source/drain (S/D) trenches 130, as shown in in accordance with some embodiments.

Next, as shown in FIG. 11C, the sacrificial layer 109 is removed to form a recess (not shown), and a middle dielectric layer 129 is formed in the recess, in accordance with some embodiments.

In some embodiments, the middle dielectric layer 129 is made of silicon nitride (SiN), silicon carbide (SiC), silicon oxynitride (SiON), silicon carbon nitride (SiCN), silicon oxycarbonitride (SiOCN), oxygen-doped silicon carbonitride (Si(O)CN), and/or a combination thereof. In some embodiments, the middle dielectric layer 129 is formed by a chemical vapor deposition (CVD), atomic vapor deposition (ALD), physical vapor deposition (PVD), or another suitable process.

Afterwards, as shown in FIG. 11D, after the middle dielectric layer 129 is formed, the first semiconductor layers 106B, 106T exposed by the S/D (source/drain) trenches 130 are laterally recessed to form notches (not shown), and inner spacer layers 220 are formed in the notches between the second semiconductor layers 108B, 108T, in accordance with some embodiments. The inner spacer layers 220 are configured to separate the source/drain (S/D) structures and the gate structures formed in subsequent manufacturing processes in accordance with some embodiments. The sidewall surface of the inner spacer layer 220 is aligned with a sidewall surface of the first middle dielectric layer 129.

It should be noted that the middle dielectric layer 129 and the gate spacer layer 126 are made of different materials. The middle dielectric layer 129 has a high etching selectivity with respect to the gate spacer layer 126. When the middle dielectric layer 129 is removed while the gate spacer layer 126 is not removed in the following process. Furthermore, the middle dielectric layer 129 and the inner spacer layer 220 are made of different materials. The middle dielectric layer 129 has a high etching selectivity with respect to the inner spacer layer 132. When the inner spacer layer 220 is removed, while the middle dielectric layer 129 is not removed in the following process.

The inner spacer layer 220 includes the first layer 214, the second layer 216 and the third layer 218. The second layer 216 is sandwiched between the first layer 214 and the third layer 218. The second layer 216 is located at the middle portion of the inner spacer layer 220.

Next, as shown in FIG. 11E, a bottom layer 233 is formed in the S/D recess 130, accordance with some embodiments. In some embodiments, the bottom layer 233 include un-doped Si, un-doped SiGe or a combination thereof.

In some embodiments, the bottom layer 233 is formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes.

Next, a first S/D structure 234 is formed on the bottom layer 233, in accordance with some embodiments. The first S/D structure 234 may include silicon germanium (SiGe), indium arsenide (InAs), indium gallium arsenide (InGaAs), indium antimonide (InSb), gallium arsenide (GaAs), gallium antimonide (GaSb), indium aluminum phosphide (InAlP), indium phosphide (InP), or a combination thereof. The first S/D structure 234 may dope with one or more dopants. In some embodiments, the first S/D structure 234 is silicon (Si) doped with phosphorus (P), arsenic (As), antimony (Sb), or another applicable dopant. Alternatively, the first S/D structure 234 is silicon germanium (SiGe) doped with boron (B) or another applicable dopant.

In some embodiments, the first S/D structure 234 is formed by an epitaxy or epitaxial (epi) process. The epi process may include a selective epitaxial growth (SEG) process, CVD deposition techniques (e.g., vapor-phase epitaxy (VPE) and/or ultra-high vacuum CVD (UHV-CVD)), molecular beam epitaxy, or other suitable epi processes.

In some embodiments, when an N-type FET (NFET) device is desired, the first S/D structure 234 includes an epitaxially growing silicon (epi Si). Alternatively, when a P-type FET (PFET) device is desired, the first S/D structure 234 includes an epitaxially growing silicon germanium (SiGe).

Next, a contact etching stop layer 235 is formed over the first S/D structure 234, in accordance with some embodiments. In some embodiments, the top surface of the contact etching stop layer 235 is higher than the top surface of the middle dielectric layer 129.

In some embodiments, the contact etching stop layer 235 is made of dielectric material, such as silicon nitride (SiN), silicon oxide (SiO₂), silicon oxynitride (SiOC), silicon carbide (SiC), oxygen-doped silicon carbide (SiC:O), oxygen-doped silicon carbonitride (Si(O)CN), or a combination thereof. In some embodiments, dielectric material for the contact etching stop layer 235 is globally and conformally deposited over the semiconductor structure 100a using CVD (such as LPCVD, PECVD, HDP-CVD, or HARP), ALD, another suitable method, or a combination thereof.

A spacer dielectric layer 236 is formed over the contact etching stop layer 235. The first spacer dielectric layer 236 overfills the space between dummy gate structures 118.

In some embodiments, the spacer dielectric layer 236 is made of dielectric material, such as un-doped silicate glass (USG), doped silicon oxide such as borophosphosilicate glass (BPSG), fluoride-doped silicate glass (FSG), phosphosilicate glass (PSG), borosilicate glass (BSG), and/or another suitable dielectric material.

Afterwards, a second S/D structure 238 is formed on the spacer dielectric layer 236, in accordance with some embodiments. As a result, the spacer dielectric layer 236 is between the first S/D structure 234 and the second S/D structure 238.

Next, as shown in FIG. 11F, a contact etching stop layer 142 is formed over the second S/D structure 238, and an interlayer dielectric layer 144 is formed on the contact etching stop layer 142, in accordance with some embodiments.

Afterwards, as shown in FIG. 11G, the dummy gate electrode layer 122 and the first dummy gate dielectric layer 120 are removed to form the trench 145, in accordance with some embodiments. Next, the first semiconductor layer 106B and 106T are removed to form a number of gaps 151. As a result, the nanostructures 108B and 108T (or channel layers 108B and 108T) with the second semiconductor material layers 108 are obtained. The number of nanostructures 108B and 108T (or channel layers 108B and 108T) may be adjusted according to actual application. In addition, the middle dielectric layer 129 is exposed by the trench 145 and the gaps 151.

Next, as shown in FIG. 11H, after the nanostructures 108′ are formed, a first gate structure 150a and a second gate structure 150b are formed to surround the nanostructures 108′ and over the isolation structure 116, in accordance with some embodiments.

The first gate structure 150a is a first type gate structure, and the second gate structure 150b is a second type gate structure. In some embodiments, the first gate structure 150a is an N-type gate structure, and the second gate structure 150b is a P-type gate structure. In some embodiments, the first gate structure 150a is a P-type gate structure, and the second gate structure 150b is an N-type gate structure. The first gate structure 150a and the second gate structure 150b extend in the second direction (e.g. Y-axis). The first gate structure 150a and the second gate structure 150b have longitudinal axes parallel to the Y direction, in accordance with some embodiments.

The bottom portion of the first gate structure 150a that are wrapped around the bottom nanostructures 108B combine with the neighboring first S/D structure 234 to form bottom transistors, e.g., p-channel nanostructure transistors. The top portion of the second gate structure 150b that are wrapped around the top nanostructures 108T combine with the neighboring second S/D structure 238 to form top transistors, e.g., n-channel nanostructure transistors.

In some embodiments, the n-channel top transistors are directly stacked above the p-channel bottom transistors thereby constructing CFET. In some embodiments, the p-channel top transistors are directly stacked above the n-channel bottom transistors thereby constructing CFET.

In some embodiments, the first gate structure 150a includes an interfacial layer (not shown), a gate dielectric layer 154, and a first gate electrode layer 156a. In some embodiments, the second gate structure 150b includes an interfacial layer (not shown), a gate dielectric layer 154, and a second gate electrode layer 156b.

It should be noted that same elements in FIGS. 1A to 11H may be designated by the same numerals and may include similar or the same materials and may be formed by similar or the same processes; therefore such redundant details are omitted in the interest of brevity. In addition, although FIGS. 1A to 11H are described in relation to the method, it will be appreciated that the structures disclosed in FIGS. 1A to 11H are not limited to the method but may stand alone as structures independent of the method. Similarly, although the methods shown in FIGS. 1A to 11H are not limited to the disclosed structures but may stand alone independent of the structures. Furthermore, the nanostructures described above may include nanowires, nanosheets, or other applicable nanostructures in accordance with some embodiments.

Also, while disclosed methods are illustrated and described below as a series of acts or events, it will be appreciated that the illustrated ordering of such acts or events may be altered in some other embodiments. For example, some acts may occur in different orders and/or concurrently with other acts or events apart from those illustrated and/or described above. In addition, not all illustrated acts may be required to implement one or more aspects or embodiments of the description above. Further, one or more of the acts depicted above may be carried out in one or more separate acts and/or phases.

Furthermore, the terms “approximately,” “substantially,” “substantial” and “about” describe above account for small variations and may be varied in different technologies and be in the deviation range understood by the skilled in the art. For example, when used in conjunction with an event or circumstance, the terms can refer to instances in which the event or circumstance occurs precisely as well as instances in which the event or circumstance occurs to a close approximation.

Embodiments for forming semiconductor structures may be provided. The semiconductor structures may include a number of nanostructures are formed over a substrate. A gate structure is formed on the nanostructures, and an S/D structure formed adjacent to the gate structure. An inner spacer layer is between the gate structure and the S/D structure. The inner spacer layer includes a first layer, a second layer and a third layer. The first layer and the second layer are made of different materials. The second layer and the third layer are made of different materials. The dielectric constant of the second layer is smaller than the dielectric constant of the first layer and the dielectric constant of the third layer. The second layer is between the first layer and the third layer. The second layer is used to reduce the dielectric constant of the inner spacer layer. Therefore, the parasitic capacitance of the semiconductor structure is reduced by forming the second layer with a relative low k material. Therefore, the performance of semiconductor device structure is improved.

In some embodiments, a method for forming a semiconductor structure is provided. The method includes forming a plurality of first semiconductor material layers and a plurality of second semiconductor material layers on a substrate, and the first semiconductor material layers and the second semiconductor material layers are alternately stacked. The method includes forming a dummy gate structure over the first semiconductor material layers and the second semiconductor material layers, and removing a portion of the first semiconductor material layers and the second semiconductor material layers to form a trench. The method also includes replacing the first semiconductor material layers with a dummy dielectric layer, and removing a portion of the dummy dielectric layer to form a notch. The method includes forming a first layer in the notch, forming a second layer on the first layer. The method includes removing a portion of the second layer to expose the first layer, and forming a third layer on the second layer. The method includes removing a portion of the third layer, a portion of the second layer and a portion of the first layer to form an inner spacer layer. A dielectric constant of the second layer is smaller than a dielectric constant of the first layer and a dielectric constant of the third layer. The method includes forming an S/D structure over the inner spacer layer, and removing the dummy gate structure. The method includes removing the dummy dielectric layer to form nanostructures, and forming a gate structure on the nanostructures. The S/D structure is adjacent to a sidewall of the nanostructures.

In some embodiments, a method for forming a semiconductor structure is provided. The method includes forming a fin structure on a substrate, and the fin structure includes a plurality of first semiconductor material layers and a plurality of second semiconductor material layers alternately stacked. The method includes forming a dummy gate structure over the fin structure, and removing a portion of the fin structure to form a trench. The method includes replacing the first semiconductor material layers with a dummy dielectric layer, and removing a portion of the dummy dielectric layer to form a notch. The method includes forming a thin layer in the notch and on sidewall surfaces of the second semiconductor material layers. The method includes forming a first layer on the thin layer, and forming a second layer on the first layer. The method includes performing a first removal process to remove a portion of the second layer, and the sidewall surfaces of the second semiconductor material layers are covered by the thin layer and the first layer. The method includes forming a third layer on the second layer, and the sidewall surfaces of the second semiconductor material layers are covered by the thin layer, the first layer and the third layer. The method includes performing a second removal process to remove a portion of the third layer, a portion of the second layer and a portion of the first layer to form an inner spacer layer and to expose the second semiconductor material layers. The method includes forming an S/D structure over the inner spacer layer and replacing the dummy gate structure and the dummy dielectric layer with a gate structure.

In some embodiments, a semiconductor structure is provided. The semiconductor structure includes a plurality of nanostructures formed over a substrate, and a gate structure formed on the nanostructures, and the gate structure includes a gate dielectric layer. The semiconductor structure includes a gate spacer layer formed on a sidewall of the gate structure, wherein a dielectric constant of the gate dielectric layer is greater than a dielectric constant of the gate spacer layer. The semiconductor structure includes an S/D structure formed adjacent to the gate structure, and an inner spacer layer between the S/D structure and the gate structure. The inner spacer layer includes a first layer, a second layer and a third layer, and a dielectric constant of the second layer is smaller than a dielectric constant of the first layer and a dielectric constant of the third layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a plurality of first semiconductor material layers and a plurality of second semiconductor material layers on a substrate, wherein the first semiconductor material layers and the second semiconductor material layers are alternately stacked;
forming a dummy gate structure over the first semiconductor material layers and the second semiconductor material layers;
removing a portion of the first semiconductor material layers and the second semiconductor material layers to form a trench;
replacing the first semiconductor material layers with a dummy dielectric layer;
removing a portion of the dummy dielectric layer to form a notch;
forming a first layer in the notch;
forming a second layer on the first layer;
removing a portion of the second layer to expose the first layer;
forming a third layer on the second layer;
removing a portion of the third layer, a portion of the second layer and a portion of the first layer to form an inner spacer layer, wherein a dielectric constant of the second layer is smaller than a dielectric constant of the first layer and a dielectric constant of the third layer;
forming an S/D structure over the inner spacer layer;
removing the dummy gate structure;
removing the dummy dielectric layer to form nanostructures; and
forming a gate structure on the nanostructures, wherein the S/D structure is adjacent to a sidewall of the nanostructures.

2. The method for forming the semiconductor device structure as claimed in claim 1, wherein the second layer is separated from the S/D structure by the first layer.

3. The method for forming the semiconductor device structure as claimed in claim 1, further comprising:
performing a treatment process before forming the first layer in the notch to form a thin layer, wherein the thin layer and the first layer are made of different materials.

4. The method for forming the semiconductor device structure as claimed in claim 1, wherein the method includes removing the portion of the third layer, the portion of the second layer and the portion of the first layer to expose the second semiconductor material layers.

5. The method for forming the semiconductor device structure as claimed in claim 1, wherein the second layer has a dishing profile with a recess after removing the portion of the second layer, and the third layer is formed in the recess.

6. The method for forming the semiconductor device structure as claimed in claim 1, wherein the second layer has a seam.

7. The method for forming the semiconductor device structure as claimed in claim 1, wherein a carbon atomic ratio of the first layer is greater than a carbon atomic ratio of the third layer.

8. The method for forming the semiconductor device structure as claimed in claim 1, wherein the nanostructure is formed along a first direction, the first layer has a first width along the first direction, the second layer has a second width along the first direction, the third layer has a third width, and the second width is greater than the first width and the third width.

9. The method for forming the semiconductor device structure as claimed in claim 1, further comprising:
forming a seed layer in the trench;
forming a bottom isolation layer over the seed layer; and
forming the S/D structure over the bottom isolation layer.

10. A method for forming a semiconductor device structure, comprising:
forming a fin structure on a substrate, wherein the fin structure comprises a plurality of first semiconductor material layers and a plurality of second semiconductor material layers alternately stacked;
forming a dummy gate structure over the fin structure;
removing a portion of the fin structure to form a trench;
replacing the first semiconductor material layers with a dummy dielectric layer;
removing a portion of the dummy dielectric layer to form a notch;
forming a thin layer in the notch and on sidewall surfaces of the second semiconductor material layers;
forming a first layer on the thin layer;
forming a second layer on the first layer;
performing a first removal process to remove a portion of the second layer, wherein the sidewall surfaces of the second semiconductor material layers are covered by the thin layer and the first layer;
forming a third layer on the second layer, wherein the sidewall surfaces of the second semiconductor material layers are covered by the thin layer, the first layer and the third layer;
performing a second removal process to remove a portion of the third layer, a portion of the second layer and a portion of the first layer to form an inner spacer layer and to expose the second semiconductor material layers;
forming an S/D structure over the inner spacer layer; and
replacing the dummy gate structure and the dummy dielectric layer with a gate structure.

11. The method for forming the semiconductor device structure as claimed in claim 10, wherein there is a first interface between the first layer and the second layer and a second interface between the second layer and the third layer.

12. The method for forming the semiconductor device structure as claimed in claim 10, wherein the second layer has a seam.

13. The method for forming the semiconductor device structure as claimed in claim 10, further comprising:
forming a seed layer in the trench;
forming a bottom isolation layer over the seed layer; and
forming the S/D structure over the bottom isolation layer.

14. The method for forming the semiconductor device structure as claimed in claim 13, wherein the third layer is between the bottom isolation layer and the second layer.

15. The method for forming the semiconductor device structure as claimed in claim 10, wherein the fin structure is formed along a first direction, the first layer has a first width along the first direction, the second layer has a second width along the first direction, the third layer has a third width, and the second width is greater than the first width and the third width.

16. A semiconductor structure, comprising:
a plurality of nanostructures formed over a substrate;
a gate structure formed on the nanostructures, wherein the gate structure comprises a gate dielectric layer;
a gate spacer layer formed on a sidewall of the gate structure, wherein a dielectric constant of the gate dielectric layer is greater than a dielectric constant of the gate spacer layer;
an S/D structure formed adjacent to the gate structure; and
an inner spacer layer between the S/D structure and the gate structure, wherein the inner spacer layer comprises a first layer, a second layer and a third layer, and a dielectric constant of the second layer is smaller than a dielectric constant of the first layer and a dielectric constant of the third layer.

17. The semiconductor structure as claimed in claim 16, wherein the nanostructure is formed along a first direction, the first layer has a first width along the first direction, the second layer has a second width along the first direction, the third layer has a third width, and the second width is greater than the first width and the third width.

18. The semiconductor structure as claimed in claim 16, further comprising:
a thin layer between the gate structure and the first layer, wherein the thin layer and the first layer are made of different materials.

19. The semiconductor structure as claimed in claim 16, further comprising:
a seed layer over the substrate;
a bottom isolation layer over the seed layer; and
the S/D structure over the bottom isolation layer.

20. The semiconductor structure as claimed in claim 19, wherein the third layer is between the bottom isolation layer and the second layer.
